(19) United States
(12) Patent Application Publication
(10) Pub. No.: US 2026/0350247 A1
(43) Pub. Date: Nov. 5, 2026

(54) METHOD AND SYSTEM FOR INTERACTIVELY GENERATING VISIO-ACOUSTIC EXTENDED-REALITY SIMULATION OF SPACES

(71) Applicant: Varjo Technologies Oy, Helsinki (FI)

(72) Inventors: Kai Inha, Järvenpää (FI); Oliver Merilaid, Helsinki (FI)

(73) Assignee: Varjo Technologies Oy, Helsinki (FI)

(21) Appl. No.: 19/198,840

(22) Filed: May 5, 2025

(51) Int. Cl. G06F 30/13; H04S 7/00

(52) U.S. Cl. CPC G06F 30/13; H04S 7/306; H04S 2400/11

(57) ABSTRACT

A computer-implemented method for interactively generating visio-acoustic extended-reality simulation of space. The method includes: defining geometry of space; defining target acoustic metrics for space; obtaining first set of materials and corresponding acoustic properties, from first database; identifying second set of materials from amongst first set of materials, by analysing correspondence between target acoustic metrics and acoustic properties of materials of first set, and geometry of space; providing, at user device, proposal for designing surface(s) of space (S1, S2, S3, S4, S5), proposal including second set of materials and corresponding acoustic properties; receiving, from user device, selection of material(s) from second set for designing surface(s) or their portions; and associating corresponding acoustic properties of material(s) to surface(s) or their portions, for generating visio-acoustic XR simulation of space.

### TECHNICAL FIELD

The present disclosure relates to computer-implemented methods for interactively generating visio-acoustic simulation in virtual reality (VR) or extended reality (XR). Moreover, the present disclosure relates to systems for interactively generating visio-acoustic simulation in virtual reality (VR) or extended reality (XR).

### BACKGROUND

In architectural design, room acoustics play a vital role in ensuring the functional and aesthetic success of a space. The acoustic behaviour of a room is influenced by various factors, including its geometry, surface materials, and furnishings. For example, an empty room with hard surfaces tends to produce excessive reverberation, while a space with absorptive materials like carpets or fabric panels dampens sound reflections, creating a quieter environment. In environments such as open offices, concert halls, or residential spaces, poor acoustic design can lead to dissatisfaction, reduced productivity, and usability issues. The challenge of optimizing acoustics becomes more complex when one considers that changes to a room's design such as swapping surface materials or rearranging furniture which affect both its visual and acoustic characteristics.

Existing equipment and techniques for addressing acoustic challenges in design rely heavily on simulation tools and static modelling techniques. Traditional tools, such as those based on numerical methods like finite element analysis (FEM) or geometrical approaches like ray tracing, are widely used in the industry to model sound propagation and room acoustics. The aforementioned tools process virtual audio sources using room impulse responses to simulate how sound behaves in a particular environment. However, while these existing solutions provide some level of acoustic prediction, they are often computationally intensive (for example, finite element method (FEM) simulation tools), time-consuming, and require expertise to interpret the results. Moreover, the aforementioned tools are generally isolated from the overall architectural design workflow, making it difficult to iteratively refine designs based on both acoustic and visual considerations simultaneously.

Despite their capabilities, the existing equipment and techniques have significant limitations that hinder their practical application. Firstly, they lack interactivity, making it challenging for designers to visualize the effects of their design choices in real time. Many existing tools (such as Odeon) are limited to static receiver source configurations, which fail to capture the dynamic variations of acoustic behaviour within a room. It may allow multiple sound sources at the same time, but the receivers also remain in fixed positions. However, it does support binauralization using Head-Related Transfer Functions (HRTFs), which helps simulate realistic 3D sound perception. Additionally, it allows 3 Degrees of Freedom (3 DoF), meaning users can rotate their head to experience changes in sound direction, but they cannot move freely within the space. Additionally, the existing techniques often focus on isolated acoustic parameters without integrating them seamlessly into the broader design process, leaving architects and designers to rely on subjective judgment or trial-and-error approaches. Moreover, the existing equipment and techniques are time consuming, error-prone and extremely expensive that, further limiting their feasibility in practical application.

Therefore, in light of the foregoing discussion, there exists a need to overcome the aforementioned drawbacks.

### SUMMARY

The aim of the present disclosure is to provide a computer-implemented method and system for interactively generating a visio-acoustic extended-reality (XR) simulation of a space to enable real-time visualization and auralization of spaces, thereby enhancing the design and evaluation of acoustic properties and spatial configurations in an immersive environment. In certain embodiments, the visio-acoustic simulation may be created entirely from scratch in a virtual space, without requiring any real-world spatial input or scanning. The computer-implemented method and system allows a user to create and model entirely new acoustical spaces in virtual reality (VR), without requiring any physical reference space. The aim of the present disclosure is achieved by computer-implemented method and system for interactively generating a visio-acoustic extended-reality (XR) simulation of a space as defined in the appended independent claims, to which reference is made. The system provides an interactive VR experience in which the user can visually design a virtual space by modifying surface materials, layout, and acoustic parameters, and simultaneously experience real-time auditory feedback of how these changes affect the space's acoustics. Advantageous features are set out in the appended dependent claims.

The embodiments of the present disclosure substantially enable the improvement of real-time interactive acoustic modelling, allowing users to dynamically adjust materials and spatial arrangements while experiencing the corresponding auditory and visual effects. The present disclosure further enhances computational efficiency by integrating acoustic simulations within an extended-reality environment, reducing reliance on traditional, computationally intensive simulation techniques.

Additional aspects, advantages, features, and objects of the present disclosure will be apparent from the drawings and the detailed description of the illustrative embodiments, which should be read in conjunction with the appended claims.

Throughout the description and claims of this specification, the words “comprise”, “include”, “have”, and “contain” and variations of these words, for example “comprising” and “comprises”, mean “including but not limited to”, and do not exclude other components, items, integers or steps not explicitly disclosed also to be present. Moreover, the singular encompasses the plural unless the context otherwise requires. In particular, where the indefinite article is used, the specification is to be understood as contemplating plurality as well as singularity, unless the context requires otherwise.

### BRIEF DESCRIPTION OF THE DRAWINGS

FIG. 1 is an illustration of a flow chart depicting steps of a computer-implemented method for interactively generating a visio-acoustic extended-reality (XR) simulation of a space, in accordance with an embodiment of the present disclosure;

FIG. 2 is an illustration of a block diagram of a system for interactively generating a visio-acoustic extended-reality (XR) simulation of a space, in accordance with an embodiment of the present disclosure;

FIG. 3A is an illustration of a three-dimensional (3D) space for which a visio-acoustic extended-reality (XR) simulation is generated, while FIG. 3B is an illustration of a top view of the 3D space of FIG. 3A, in accordance with an embodiment of the present disclosure; and

FIGS. 4A and 4B are simplified illustrations of side view of exemplary soundscapes of a space, in accordance with different embodiments of the present disclosure.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practising the present disclosure are also possible.

In a first aspect, the present disclosure provides a computer-implemented method for interactively generating a visio-acoustic extended-reality (XR) simulation of a space, the method comprising:
defining a geometry of the space;
defining target acoustic metrics for the space;
obtaining a first set of materials and their corresponding acoustic properties, from a first database;
identifying a second set of materials from amongst the first set of materials, by analysing a correspondence between the target acoustic metrics and the acoustic properties of the materials of the first set, and the geometry of the space;
providing, at a user device, a proposal for designing one or more surfaces of the space, the proposal including the second set of materials and their corresponding acoustic properties;
receiving, from the user device, a selection of one or more materials from the second set for designing the one or more surfaces or their portions; and
associating corresponding acoustic properties of the one or more materials to the one or more surfaces or their portions, for generating the visio-acoustic XR simulation of the space.

In a second aspect, the present disclosure provides a system for interactively generating a visio-acoustic extended-reality (XR) simulation of a space, the system comprising:

a data repository having stored thereat at least a first database comprising acoustic properties of a plurality of materials; and

a processor communicably coupled to the data repository, wherein the processor is configured to:
define a geometry of the space;
define target acoustic metrics for the space;
obtain a first set of materials and their corresponding acoustic properties, from the first database;
identify a second set of materials from amongst the first set of materials, by analysing a correspondence between the target acoustic metrics and the acoustic properties of the materials of the first set, and the geometry of the space;
provide, at a user device, a proposal for designing one or more surfaces of the space, the proposal including the second set of materials and their corresponding acoustic properties;
receive, from the user device, a selection of one or more materials from the second set; and
associate corresponding acoustic properties of the one or more materials to the one or more surfaces or their portions, to generate the visio-acoustic XR simulation of the space.

The present disclosure provides the aforementioned computer-implemented method and the aforementioned system to facilitate an accurate, reliable, high-quality and real-time visualization and auralization of the space that ensures precise alignment of an acoustic environment with the physical layout and enhances the accuracy of acoustic designs and predictions. The system provides an interactive VR experience in which the user can visually design a virtual space by modifying surface materials, layout, and acoustic parameters, and simultaneously experience real-time auditory feedback of how these changes affect the space's acoustics. In certain embodiments, the visio-acoustic simulation may be created entirely from scratch in a virtual space, allowing the user to define the geometry, materials, and acoustic properties without requiring any real-world spatial input or scanning. Alternatively, the system is able to support partially virtual spaces, where predefined geometries or materials are used as a starting point for further customization. In extended reality (XR) embodiment, the visuals and acoustic is based on the real-world space around the user, where the user is able to add virtual materials, modify existing geometry and define acoustic parameters to simulate and optimize the space (e.g., a concert hall or an open office). For example, a user can sit or stand in their office, wearing a Head-Mounted Display (HMD) device and interactively design a virtual concert hall or an office space, experiencing the acoustics and visual properties of the virtual concert hall, open office, or any other space in real-time. The visio-acoustic XR simulation is useful for designing spaces that do not yet exist or for exploring hypothetical acoustical scenarios of a space. The ability to define the target acoustic metrics and identify the materials that correspond to these metrics enables the creation of the space optimized for specific acoustic goals, such as minimizing reverberation time, minimizing noise level or enhancing speech intelligibility. The inclusion of the first and the second database in the data repository allows to leverage pre-existing knowledge for accurate and efficient analysis. The integration of the extended-reality (XR) technology allows the users to visualize and experience the proposed acoustic configurations in an immersive environment, leading to more informed decision-making during the design process. By analyzing the correspondence between the target acoustic metrics, material properties, and space geometry, the computer-implemented method automates the filtering of the feasible materials, saving time and reducing reliance on trial-and-error methods. Additionally, depending on the specific use case, factors such as sound sources, their location, level, and signal content may also be considered Moreover, presenting the proposal to the user device and enabling the user feedback creates an interactive loop that enhances the user engagement and ensures that the final design align with the user preferences.

Throughout the present disclosure, the term “visio-acoustic extended-reality simulation” refers to an immersive and interactive virtual representation of a space that combines visual elements with acoustic elements. The visio-acoustic simulation is performed using extended-reality (XR) technologies, wherein XR encompasses augmented reality (AR), virtual reality (VR), or mixed reality (MR), and similar technologies, to provide a realistic and interactive experience of both the visual appearance and the acoustic behavior of the space. The term “space” refers to a physical or virtual environment that comprises boundaries such as surfaces and/or objects within it. For example, the space may include, but are not limited to, architectural interiors (such as, virtual rooms, virtual concert halls, virtual auditoriums and similar), virtual outdoor environments (such as open plazas, courtyards and similar) and similar. It will be appreciated that the space may be an entirely virtual space created from scratch, where the geometry, materials, and acoustic characteristics are defined by the user without any reference to a real-world space. The visio-acoustic extended-reality simulation simulates the space both visually and acoustically. It will be appreciated that in the XR embodiment, the visio-acoustic extended-reality simulation allows the user to add virtual materials, modify existing geometry and define acoustic parameters to stimulate and optimize the space. The visio-acoustic extended-reality simulation simulates the space both visually and acoustically, allowing the user to virtually perceive and interact with a realistic representation of the space, incorporating its geometry, materials, and acoustic characteristics, whether the space is entirely virtual, partially virtual, or based on a real-world environment.

Throughout the present disclosure, the term “geometry” refers to spatial configuration and physical structure of the space. Typically, the geometry may include quantitative and qualitative attributes that describes layout, dimensions, and arrangement of the space. The geometry of the space determines how sound waves interact (such as, reflecting, absorbing, scattering or diffusing) with the surface(s), affecting the acoustic behavior of the space. For example, the user is able to define the geometry of a virtual concert hall, including its dimensions, seating arrangements, and stage designs, without referencing to the real-world space. It will be appreciated that accurately defining the geometry enables precise tailoring of the space for various use cases, such as, optimizing speech clarity or reducing reverberation, and similar, within the space in the VR environment. The process of defining the geometry involves receiving spatial data in various forms, such as architectural drawings, 3D models, raw measurements, user-provided images or scans, and similar, followed by image processing to extract spatial details. Then, the spatial data is converted into a digital representation of the space. It will also be appreciated that the geometry, the materials and the acoustic properties of a virtual space are defined from scratch, without requiring any physical reference space. Alternatively, the virtual space is a pre-existing virtual model that the user is able to modify and customize in the VR, allowing for adjustments to the geometry, materials and the acoustic properties as needed.

Optionally, the geometry of the space comprises at least one of: spatial dimensions, a number of surfaces, physical surface design information, pre-defined surface material information, object information, environmental context, acoustic zones, of the space. In this regard, the term “spatial dimensions” refers to measurable extents of the space in three-dimensional coordinates. The spatial dimensions may include dimensions (for example, length, width and height of the space), volume of the space, shape of the space (for example, rectangular, square or more complex shapes with walls in between and the like, or any materials inside the space (for example, width, height, depth, and location for an absorptive material). The spatial dimensions impact how the sound waves interact with the surfaces, creating reverberation, flutter echo. The number of surfaces may include walls, floors, ceilings, partitions, and similar architectural elements that form enclosure of the space, or even open doors. Moreover, the number of surfaces may include surfaces within the space serving specific functions, such as acoustic panels, furniture, decorative elements, and similar that influence sound reflection, absorption, scattering, or diffusion. The physical surface design information includes information regarding layout of surface(s), inclination/curvature of the surface(s), location and size of opening(s) in surface(s). The pre-defined surface material information refers to an information or attribute associated with the material that is already known, specified or cataloged for the surface(s) of the space. For example, some surface(s) may have fixed material properties which cannot be changed, and these properties should be considered when modelling acoustics of the space. As an example, for a sea-facing room in a skyscraper, a surface facing the sea may be made entirely of glass, for providing a good sea-view. The object information is a data associated with distinct objects present within the space. The objects may include furniture, fixtures, equipment, decorative objects, and similar elements that interact with the geometry of the space. It will be appreciated that the object information may include size, shape, and volume of the object, which are crucial for understanding how the object interacts with sound waves. The environmental context includes information of adjacent connected spaces, outdoor noise sources around the space, and similar. The acoustic zones refers to specific areas within the space that exhibit distinct acoustic characteristics. Each acoustic zone is defined based on the intended function of said area. For example, a quite zone for focused work in a library, a reverberant zone for enhancing musical performance in a concert hall, and similar. It will be appreciated that the acoustic zones enable creation of multi-functional space that can adapt acoustically to different activities or events. Spatial dimensions of the space help to determine the amount and placement of materials to achieve the desired acoustic properties. A technical effect of the aforementioned feature is that it ensures that the visio-acoustic extended reality simulation align closely with real-world conditions and improves the realism and accuracy of the visio-acoustic extended reality simulation.

Throughout the present disclosure, the term “target acoustic metrics” refers to a set of predefined or user-defined acoustic performance parameters or objectives that describe the desired acoustic characteristics of the space. The target acoustic metrics serve as benchmark to guide the design of the space and the simulation process in achieving intended acoustic environment. For example, STI score>=0.75, noise level when the space is unoccupied is 30-35 dB, reverberation time (RT60)<0.6 seconds and similar. It will be appreciated that the target acoustic metrics can be set based on industry standards or regulatory standards for particular types of spaces (for example, classrooms, meeting rooms and similar). Optionally, the target acoustic metrics may be defined by the user based on specific use cases or preferences. It will also be appreciated that defining the target acoustic metrics ensures that the space meets its functional requirements, whether for speech clarity, immersive audio, noise reduction, and similar. For example, meeting rooms focus on speech intelligibility and low noise level, concert halls emphasize balanced reverberation for musical richness, and similar.

Optionally, the target acoustic metrics comprise at least one of: Speech Transmission Index (STI), noise level, reverberation time (RT60), audio level, clarity and intelligibility parameters, spatialization parameters, auditor envelope. In this regard, the term “speech transmission index” refers to a quantitative metric that measures the intelligibility of speech in the space. The speech transmission index (STI) evaluates the degree to which the speech is preserved after being transmitted through the space, considering factors, such as background noise, reverberation, distortion, frequency response, and similar. It will be appreciated that the STI is included as a target acoustic metric to ensure that the space is designed to facilitate optimal speech intelligibility for its intended use, such as communication, public announcements, or presentations. For example, the target acoustic metrics comprises the STI score>=0.75 for the place. The term “noise level” refers to an intensity of background or ambient sound within the space. Additionally, the noise level can include other types of sounds present in a specific space at a specific distance. Typically, the noise level is measured in decibels dB(A). For example, background noise levels can be specified as ‘30 dB A-weighted’ or ‘30 dB(A)’. The background noise level within the space is measured using a sound level meter (SLM) following standardized methodologies. For example, in Europe, A-weighted equivalent continuous sound level (LAeq) is commonly used. The LAeq represents the time-averaged sound levels over a given period, accounting for fluctuations. In the USA, different metrics such as NC (Noise Criterion) levels may be used. The noise level includes unwanted sound generated by external or internal sources such as traffic, HVAC system, crowd noise, and similar. The noise level is one of the acoustic parameters in designing the space, as excessive noise can interfere with speech intelligibility and overall sound quality. For example, in a meeting room, the typical noise level when unoccupied is 30-35 dB A-weighted. However, it is not always ideal to aim for the lowest possible background noise level in all spaces. For example, in an open office environment, a certain level of background noise can help mask distractions and improve overall productivity. The term “reverberation time” refers to a time taken by sound energy in the space to decay after the sound source has stopped emitting. For example, the reverberation time 60 (RT 60) is the time it takes for the sound energy in the space to decay by 60 dB after the sound source has stopped emitting. It will be appreciated that the RT60 is considered as the target acoustic metric to ensure that the space achieves a balance between clarity and natural sound resonance. The term “audio level” refers to an amplitude or an intensity of the sound produced within the space. The audio level represents the desired loudness of an audio content. It will be appreciated that the audio level is specified as the target acoustic metrics to ensure the sound in the space is neither too loud (causing discomfort or distortion) nor too quiet (resulting in poor audibility). The term “clarity and intelligibility parameters” refers to parameters that assess how well speech or sound details are preserved and understood in the given space. For example, the clarity and intelligibility parameters may include Early-to-Late Sound Energy Ratio, Music Clarity Index and the like. Higher clarity values indicate better intelligibility, which is critical for spaces like conference rooms, classrooms, and auditoriums. The term “spatialization parameters” refers to parameters that determine how the sound is perceived in terms of directionality, distance, and localization within the space. The spatialization parameters help in simulating realistic spatial sound effects and ensuring accurate perception of the sound sources. For example, the spatialization parameters may include interaural time difference, interaural level difference, binaural cues and 3D audio processing. The term “auditor envelope” refers to temporal and spatial characteristics of how sound energy evolves in the space, impacting perception of the sound within the space. The auditor envelope may include sound decay profile (how sound energy diminishes over time), perceived loudness envelope (variations in sound intensity over its duration) and the like.

The target acoustic metrics comprise at least one of: Speech Transmission Index (STI), noise level, reverberation time (RT60), audio level, clarity and intelligibility parameters, spatialization parameters, auditor envelope ensures that the space performs as intended acoustically, addressing issues like speech intelligibility, excessive noise, imbalanced sound levels, reflections (flutter echo in small spaces, echo in larger spaces, lateral reflections in concert halls) and similar. It will also be appreciated that the aforementioned target acoustic metrics allows for design of the spaces with specific acoustic needs, such as auditoriums, offices, meeting rooms, home theaters, and similar. A technical effect of using different metrics in the target acoustic metrics is to ensure that the resulting acoustic space aligns closely with user expectations, whether the priority is speech clarity, immersive sound, or noise reduction. The flexibility to define different metrics allows the system to adapt to a wide range of applications and use cases.

Throughout the present disclosure, the term “materials” refers to physical substances or compositions that are used to design or construct the surface(s) of the space. The first set of materials may include natural materials (for example, wood, stone, glass, and similar), synthetic materials (for example, foam, polymers, and similar) and similar. The term “acoustic properties” refers to quantifiable characteristics of the materials that influences the interaction of the sound waves with the materials. For example, the acoustic properties may include absorption coefficient, reflection coefficient, diffusion coefficients, scattering coefficients, transmission loss, resonance frequency, impedance, porosity and the like. Herein, the corresponding acoustic properties are the acoustic properties of the first set of materials. The acoustic properties determine how the sound is absorbed, reflected, transmitted, scattered, and similar, by the first set of materials when used in the visio-acoustic extended-reality simulation of the space. Additionally, depending on the specific use case, factors such as sound sources, their location, level of sound, and signal content may also be considered. For instance, noise level reduction requires knowledge of the sound sources. Similarly, for Speech Transmission Index (STI) calculations, the location of both the source and a listener can be relevant. In actual auralization process, the aforementioned factors are always significant, ensuring a more accurate and realistic visio-acoustic simulation. It will be appreciated that the system serve as an interactive tool for modeling and improving room acoustics. The user is able to experiment with different materials, geometries, and acoustic parameters in a virtual environment, and receive real-time feedback on how the aforementioned changes affect the acoustics and visuals of the space. This capability makes the system invaluable for architects, designers, and acousticians and the like.

The term “database” refers to a structured collection of data or information that stores details about the first set of materials and their corresponding acoustic properties. The first database serves as a repository from which the first set of materials is retrieved for the visio-acoustic extended-reality simulation of the space. Optionally, the database may be hosted locally on a user device, stored in cloud, or integrated with external repositories. It will be appreciated that by providing the first set of materials with their corresponding acoustic properties, it empowers the user to make informed choices that align with the target acoustic metrics.

Throughout the present disclosure, the phrase “second set of materials” refers to a subset of materials selected from the first set of materials based on their suitability for achieving the target acoustic metrics. The term “correspondence” refers to a relationship or a degree of alignment between the target acoustic metrics, the acoustic properties of the materials of the first set, and the geometry of the space. The correspondence is determined through an analysis that evaluates compatibility of the acoustic properties of the materials of the first with the predefined requirements of the geometry of the space and the target acoustic metrics. The acoustic properties of the first set of materials are assessed for compatibility with the target metrics. The geometry of the space is factored into account for how the sound will interact with the surface(s) and the spatial dimensions. The materials that meet or exceed the requirements of the target acoustic metrics are identified as part of the second set. It will be appreciated that filtering out the second set of materials from the first set of materials narrows down the options to only those materials that enables achievement of the target acoustic metrics, given the geometry of the space and reduces likelihood of suboptimal design choices.

Optionally, the step of identifying the second set of materials from amongst the first set of materials is performed by employing at least one of: a logical operation, a simulation, an artificial intelligence algorithm. In this regard, the term “logical operation” refers to a predefined, rule-based computational procedure or algorithm to analyze and evaluate the acoustic properties of the first set of materials with the target acoustic metrics, given the geometry of the space. For example, the logical operation may include conditional checks, such as verifying if the material's absorption coefficient falls within a range specified by the target reverberation time (RT60). The term “simulation” refers to a computational modeling of real-world physical phenomena of the interaction of sound waves with the materials and geometry of the space to evaluate how well the materials meet the target acoustic metrics. The artificial intelligence (AI) can autonomously evaluate the first set of materials and the corresponding acoustic properties to identify the second set of materials. For example, an AI algorithm is trained to predict the acoustic performance of the material under specific conditions by learning from historical data and simulations. For example, a neural network can be trained on past material data to predict absorption coefficients based on room geometry. It could rank the materials based on their predicted performance and optimizes the selection process. A technical effect of the aforementioned feature is to improve the accuracy of identifying the second set of materials that align with the target acoustic metrics and the geometry of the space. It automates a complex and time-consuming identification process, allowing a rapid analysis of the first set of materials and reducing manual effort.

Throughout the present disclosure, the term “user device” refers to a computational device that enables interaction between the user and the system. For example, the user device may include, but are not limited to, a head-mounted display (HMD) device, an extended-reality (XR) device, smartphones, tablets, computers and the like. Optionally, it will be appreciated that the HMD device is communicable coupled to an audio device. For example, the audio device may include a headphone, a stereo speaker, and the like. The user is able to adjust volume level of the audio device by increasing or decreasing the volume level as per his comfort level. The audio device is used by the user to hear the virtual sound generated by the at least one sound source in the virtual space. The term “surfaces” refers to physical or virtual boundaries or components within the space that are subject to design or material application for achieving the desired acoustic properties. It will be appreciated that the one or more surfaces may have a single surface or a plurality of surfaces. Typically, the one or more surfaces may include walls, floors, ceilings, surfaces of movable or fixed objects and the like. Moreover, the acoustic properties of the material are not solely determined by its surface characteristics but are also influenced by the underlying materials and the overall depth of a material assembly. A structural composition, including substrate layers, backing materials, and air gaps, significantly impact sound absorption, reflection, scattering, and transmission properties. Furthermore, variations in the material thickness, even within the same material type, can result in distinct acoustic behaviors and should be treated as separate material choices. The term “proposal” refers to a systematically generated set of recommendations or design options for constructing or modifying the one or more surfaces of the space. For example, the user is able modify the materials of the walls, ceiling, and floor, and observes how these changes affect the acoustics and visuals of the space in real-time. The proposal is tailored to meet specific requirements, such as achieving the target acoustic metrics defined for the space. For example, covering the ceiling with an absorption material reduces reverberation and changes the sound reflections, which are both heard and visualized in the VR environment. This allows the user to observe how such modifications impact the acoustics of the space in real-time, enabling informed decisions about material choices. The second set of materials and their acoustic properties are presented as the proposal on the user device and serve as an interactive output for review, selection, and further design customization. The proposal includes the second set of materials and their corresponding acoustic properties that is used to design the one or more surfaces of the space. However, some surfaces amongst the one or more surfaces may have pre-specified material specifications, based on user preference, design regulations and the like, which cannot be changed. For example, in a sea-facing meeting room, the sea-facing wall of the meeting room is made up of the glass material for a better sea-view. While such surfaces must remain of a specific type, such as a window, their thickness, coatings, or other parameters can still be adjusted to optimize acoustic performance. These variations may significantly impact acoustics, even though the surface must remain a window or a specific material type due to functional or aesthetic requirements. It will be appreciated that the phrase “one or more surfaces of the space have to be designed” encompasses both scenarios, where only selected surfaces of the space are to be designed and where all surfaces of the space are to be designed. It will be appreciated that the aforementioned feature ensures that the user is presented with an informed and interactive option to choose suitable materials for the one or more surfaces of the space. It enables efficient design planning by incorporating the acoustic properties that meet the predefined target acoustic metrics, aligning with the user's requirements or constraints. It will also be appreciated that incorporation of the second set of materials tailored to the target acoustic metrics improves precision of the visio-acoustic extended-reality simulation.

Throughout the present disclosure, the term “selection” refers to a process to choose one or more materials from the proposed second set of materials for designing the one or more surfaces (or portions of the surfaces) in the space. It is to be noted that the selection is made using the user device, which can involve various methods of interaction, such as touchscreen gestures, mouse clicks, voice commands, or controllers (e.g., in the XR device) or hand control without separate controllers and the like. It will be appreciated that a single material can be selected for an entirety of the surface, or different materials may be selected for different surface, or different materials may be selected for different portions of the surface. For example, a portion of the floor surface may be wooden while another portion of the floor surface may be carpeted concrete. It allows the user to personalize the design of the space by choosing the materials from the second set of materials based on the target acoustic metrics. Moreover, receiving the selection from the user device ensures that the design of the one or more surfaces and their portions accounts for practical constraints such as noise level, budget, material availability, and regulatory requirements. The aforementioned feature demonstrates how the method effectively combines computational intelligence with human expertise to produce precise and contextually appropriate visio-acoustic XR simulation of the space. It will be appreciated that the computer-implemented method provides real-time feedback, allowing the user to modify the design and observe the resulting changes in acoustics and visuals of the space. This interactive approach makes a powerful tool for designing and optimizing spaces that do not yet exist as well as for modifying existing spaces to improve their room acoustics.

Throughout the present disclosure, the corresponding acoustic properties of the one or more materials is associated to the one or more surfaces or portions of the surfaces in the space. This association forms the basis for generating the visio-acoustic XR simulation, where both visual and acoustic characteristics of the space are represented. It will be appreciated that the association of the acoustic properties with the one or more surfaces ensures that the simulation reflects real-world behavior and enables accurate predictions of how the sound interacts with the designed space. The process bridges user-defined design choices with technical parameters, allowing the user to visualize and evaluate the impact of their selections in a simulated environment. The simulation combines visual and acoustic information to provide a comprehensive experience, aiding in better decision-making for designing the space. Moreover, each material in the second set of materials has predefined acoustic properties. These acoustic properties are mapped to the corresponding one or more surfaces or portions of surfaces selected by the user. It will be appreciated that the association of the acoustic properties with the one or more surfaces or the portions of the surfaces allows to generate the visio-acoustic XR simulation of the space that can validate design choices before actual implementation, saving time and costs. It will also be appreciated that the association enables iterative refinement of the materials and the surfaces in the design, offering flexibility to optimize the space for both acoustic and visual goals.

Optionally, the computer-implemented method further comprises:
providing the visio-acoustic XR simulation of the space, at an XR device;
receiving a test input indicative of:
   a location and audio properties of at least one virtual sound source in the visio-acoustic XR simulation of the space, and
   a location of at least one sound receiver in the visio-acoustic XR simulation of the space;
simulating emission of at least one sound by the at least one virtual sound source; and
generating a soundscape comprising an auditory response received at the at least one sound receiver, corresponding to the simulated emission of the at least one sound.

In this regard, the term “XR device” refers to a specialized equipment that is configured to present an extended-reality (XR) environment to the user, when said XR device, in operation, is worn by the user on his/her head. The XR environment encompasses augmented reality (AR), virtual reality (VR), or mixed reality (MR) and the like. In an implementation, the XR device is implemented as a head-mounted device (HMD). It is to be noted that the XR device acts as an interface through which the user experiences the visio-acoustic XR simulation of the space. It allows the user to experience the space in a realistic XR environment in three-dimensional (3D), helping them better understand the design's visual and acoustic impacts. The term “test input” refers to a set of user-provided inputs or system-generated inputs entered into the system to stimulate and analyze acoustic interactions in the visio-acoustic XR simulation of the space. The term “virtual sound source” refers to an object from which a sound emanates in the visio-acoustic XR simulation. It is to be noted that the at least one virtual sound source is not a physical sound emitter but a digital representation of a sound source, designed to replicate real-world acoustic behaviors in the simulated space. Such an object could be a living object (for example, such as a human, an animal, and the like) or a non-living object (for example, such as a musical instrument, an electronic device, a vehicle, and the like). The musical instrument could, for example, be a guitar, a piano, a drum, a violin, or the like. The electronic device could, for example, be a television, a cell phone, an alarm clock, a speaker, or the like. The location of the at least one virtual sound source is spatial coordinates within the XR environment where the sound source is positioned. The term “audio properties” refers to attributes or characteristics of the virtual sound source that define how it behaves acoustically and interacts with the environment in the visio-acoustic XR simulation. The audio properties may include frequency, amplitude, waveform or type of sound, and the like. Moreover, the audio signal has a specific waveform, a specific loudness, a specific spatial characteristic (directionality), it can be periodic, or non-periodic. Frequency content can change over time (for example, speech), or it can be same (pure sine signal). The audio properties facilitates replicating realistic sound experience in the visio-acoustic XR simulation space.

The term “sound receiver” refers to an object or entity that receives sound in the visio-acoustic XR simulation. For example, the at least one sound receiver is the user wearing the HMD device to observe the visio-acoustic property of the virtual space. It is important to note that the sound receiver is not a physical entity but a digital representation of the sound receiver that is designed to simulate the reception of sound in the XR environment. The sound receiver could be a living being (for example, such as a human, an animal, and the like) or a non-living entity (for example, such as a microphone, an ear, a speaker, or the like). The non-living entities could include objects like hearing aids, audio recording devices, or specialized equipment designed to capture or measure sound. The sound receiver is used to evaluate the impact of the virtual sound source on the perceived acoustics in the visio-acoustic XR simulation space. The location of the at least one sound receiver is spatial coordinates within the XR environment where the sound receiver is positioned. Moreover, information regarding the location of the virtual sound source and the location of the sound receiver is essential to assess acoustic design of the space. It helps to evaluate the interaction between the sound and the space. By knowing where the sound source and the sound receiver is located and their respective audio characteristics, accurate simulations of sound propagation and reception can be created. A technical effect of the aforementioned features is that the test input provides a foundation for detailed acoustic modeling and testing within the XR environment. This leads to more accurate simulations of how sound behaves in real-world or conceptual spaces. Additionally, the test input allows the user to experiment with different sound placements, properties, and receiver configurations. This supports iterative design of the space in the visio-acoustic XR simulation, offering flexibility to test various acoustic setups to meet the target acoustic metrics.

It will be appreciated that a simulated sound output is generated from the at least one virtual sound source within the visio-acoustic XR simulation. The emission of the at least one sound provides auditory cues that contribute to a sense of presence and realism. By simulating the emission of the sound from the at least one virtual source, the simulation aims to replicate how sounds behave in real-world spaces and enhances immersive experience of the user. The term “soundscape” refers to an auditory environment or an acoustic scene that is perceived in the space. It is to be noted that the soundscape encompasses all the sounds that exist within the XR environment, including both the at least one sound generated by the simulation and resulting interactions (such as reflections, reverberations, and absorptions). For example, a virtual concert hall simulation would have a soundscape comprising the sound of instruments, their reflections off walls, the reverberation in the space, and the ambient noise from the audience. The soundscape provides context for the user by simulating how the sound behave in a particular space, allowing for an accurate representation of how the user would hear the simulated environment. The term “auditory response” refers to a perception of the sound received by the sound receiver after the emission of the at least one sound. The auditory sound is influenced by the physical characteristics of the space, including the geometry, the materials, the reverberation, reflections, and other acoustics properties. It is to be noted that the auditory response may include information indicative of at least one of: direct sounds, early reflections, late reflections, of the at least one sound. Moreover, the auditory response will include amplitude, direction of arrival, etc. of the at least one sound. Each sound receiver receives a distinct auditory response which may be influenced by its directionality characteristics. For example, in the case of human perception, ears exhibit directional sensitivity, modeled using Head-Related Transfer Functions (HRTFs). Instead of computing a single room impulse response, two impulse responses, one for each ear is calculated to enable binaural perception of audio. By incorporating this method, the system can support spatial audio playback, which is an essential aspect of realistic acoustic simulations. A technical effect of the aforementioned feature is to ensure that the user can place the at least one virtual sound source and the sound receiver to evaluate how the sound behaves within the space, enabling hands-on exploration and optimization. Additionally, by receiving the auditory response, the user can modify the materials, layouts, or acoustic zones in the visio-acoustic XR simulation to achieve desired performance, reducing the need for physical prototyping or manual calculations.

Optionally, the step of generating the soundscape comprises:
generating an impulse response indicative of how sound is expected to propagate in the space, based on the geometry of the space and the acoustic properties of the one or more materials; and
convolving the generated impulse response with the at least one sound, for generating the auditory response.

In this regard, the term “impulse response” refers to a mathematical representation that depicts how a short, idealized sound pulse emitted by the at least one sound source propagates through the space and is received at the sound receiver. The impulse response encapsulates behaviour of sound wave propagation in the space, considering the geometry of the space and the acoustic properties of the one or more material. A commonly used term for the impulse response is Room Impulse Response (RIR), which characterizes how sound interacts within an enclosed environment. Additionally, for XR applications and headphone-based listening experiences, Binaural Room Impulse Responses (BRIRs) are utilized to simulate spatial audio perception, ensuring a more immersive and realistic auditory experience. It represents how a single impulse, modeled as a Dirac delta function, is transformed as it travels between a source-receiver pair within the space. While an ideal impulse remains unchanged when convolved with an audio signal, the room impulse response (RIR) consists of multiple impulses caused by reflections from surfaces within the space. As the reflections occur, they undergo various alterations, such as attenuation (loss of level), frequency response modifications, and scattering into multiple reflections, before being received by the receiver with specific time delays. When an audio signal is convolved with the room impulse response, all these delayed and altered impulses contribute to the perceived sound, simulating real-world acoustics. Notably, an echo is characterized by a single additional impulse with a large delay, whereas reverberation results from numerous closely spaced reflections with shorter delays, creating a sustained sound decay over time. It characterizes the acoustic behaviour of the space by detailing arrival times of the sound at different points, amplitude (for example, overall amplitude, but also level per frequency i.e. frequency response) variations due to absorption, diffusion, scattering, and reflected by the one or more surfaces within the space, temperature, humidity and the like. Additionally, the sound loses power over distance such as, longer a reflection path is, the more it loses power. In addition to this, higher frequencies can be absorbed differently than lower frequencies. The impulse response is generated for unique combination of the geometry, the one or more materials, and the acoustic properties of the one or more materials within the space. The geometry of the space is used to calculate how the sound waves propagate. The acoustic properties of the one or more materials determine how the one or more surfaces of the space affects the sound. It will be appreciated that a computational model simulates the behavior of the sound waves. The impulse response is mathematically combined with the sound emitted by the virtual sound source. This convolution produces the auditory response, which simulates how the sound is perceived at the location of the sound receiver in the space. It will be appreciated that by generating the impulse response and convolving it with the sound, the auditory response is achieved, reflecting physical phenomena like direct sound, reflections, reverberation, and material-based absorption. A technical effect of the aforementioned feature is to ensure that the user can visually experience the sound waves propagation in the space, making the space more valuable and interactive. Additionally, the aforementioned feature captures detailed sound behaviors, including reflections, absorption, and reverberation, providing a precise sound simulation for design validation or training purposes.

Optionally, the impulse response is generated using at least one of: a numerical simulation processing, a geometrical acoustic processing. In this regard, the term “numerical simulation processing” refers to a simulation processing method that is used to simulate sound wave propagation in the space based on physical modeling of wave behavior. It is to be noted that the numerical simulation processing uses numerical techniques to solve mathematical equations, such as partial differential equations (PDEs), that describe acoustic wave phenomena, including diffraction, interference, and scattering. For example, common numerical techniques may include Comsol finite element methods (FEM) simulation tool, finite difference time domain (FDTD), boundary element methods (BEM) and the like. It will be appreciated that the numerical simulation processing is suitable for capturing complex acoustic effects in the spaces with intricate geometries or detailed surface features. The term “geometrical acoustic processing” refers to a computational method that is used for simulating sound propagation in the space by approximating the sound waves as rays. It is to be noted that the geometrical acoustic processing apply principles of ray tracing (for example, Odeon tool) to model the behavior of the sound based on geometric interactions, such as reflection, absorptions, scattering and diffusion. Additionally, Comsol finite element methods (FEM) simulation tool supports hybrid method. It applies the numerical simulation processing (wave-based) for low frequency sounds and apply principles of ray tracing for high frequency sound. The geometric acoustic processing treats the sound as straight-line rays, assuming high-frequency dominance where wave effects like diffraction are negligible. It handles large and complex spaces efficiently by focusing on ray paths and their interactions with the one or more surfaces. The aforementioned processing methods are often used to generate the impulse response as an output, that can be then convolved with the sound source to generate the auditory response. It will be appreciated that the system leverages well-known principles of acoustics, such as sound reflections, wave propagation, and absorption coefficients, to simulate the acoustic properties of the space. The principles are implemented using computational methods like ray tracing and numerical wave-equation solving. It provides an interactive VR environment where the user is able design and experience virtual spaces in real-time. A technical effect of using the numerical simulation processing is that it provides highly accurate modeling, ensuring that the wave-based phenomena like interference and diffraction are captured in the simulation. A technical effect of using the geometrical acoustic processing is to ensure faster computation while delivering a realistic approximation of the sound behavior. The flexibility to use either both processing methods or even hybrid method, mixing method ensure that the method can be applied across a wide range of scenarios, from detailed acoustic designs to fast simulations in gaming or virtual environments.

Optionally, the computer-implemented method further comprises:
providing the soundscape in the visio-acoustic XR simulation of the space;
receiving test feedback indicative of whether the target acoustic metrics for the space are achieved, based on the provided soundscape; and
maintaining the visio-acoustic XR simulation of the space, based on the test feedback.

In this regard, the term “test feedback” refers to a data or input that is provided in response to the generated soundscape within the visio-acoustic XR simulation. The test feedback evaluates whether the space's current acoustic properties, as experienced in the visio-acoustic XR simulation, align with the target acoustic metrics. The test feedback can be qualitative (e.g., user preferences) or quantitative (e.g., numerical acoustic measurements). It is to be noted that the soundscape is provided in the visio-acoustic XR simulation of the space. It ensures that the user is able to hear the auditory response at various locations in the space, for interactive testing and design optimization. information related to the interactive testing is gathered to evaluate whether the space meets the target acoustic metrics. The test feedback is incorporated into the visio-acoustic XR simulation of the space by adjusting the acoustic properties of the one or more materials, the geometry of the space or sound source configurations and updating the soundscape to reflect the modified acoustic behavior of the space. A technical effect of the aforementioned feature is to ensure that it enables continuous adaptation of the visio-acoustic XR simulation based on the test feedback, fostering a more accurate design process. Additionally, it reduces the need for costly physical prototyping or trial-and-error by iterating directly in the XR environment.

Optionally, when the test feedback indicates that the target acoustic metrics for the space are achieved, the method further comprises storing the visio-acoustic XR simulation of the space, in a second database, wherein the stored visio-acoustic XR simulation of the space is accessible for generating future visio-acoustic XR simulations of other spaces. In this regard, the term “second database” refers to a structured digital repository that is used for storing validated and finalized visio-acoustic XR simulation of the space. It is to be noted that storing successful simulations in the second database eliminates the need to repeat computationally intensive process of defining the geometry, selecting the materials, and validating the acoustic metrics for similar spaces. Moreover, once the test feedback confirms that the target acoustic metrics are met for the space, the simulation is flagged as successful. The validated visio-acoustic XR simulation, along with its associated data (e.g., the geometry, the acoustic properties of the materials, soundscape) is stored in the second database. The second database is designed to allow retrieval of stored simulations to be used as a reference or foundation for generating future visio-acoustic XR simulations of other spaces. A technical effect of storing the successful visio-acoustic XR simulation in the second database is to ensure that it minimizes the need for recalculating complex geometries and acoustic properties, hence saving processing time and resources of the user. Additionally, designers can quickly generate the visio-acoustic XR simulations for new spaces by referencing stored data, accelerating project timelines.

Optionally, when the test feedback indicates that the target acoustic metrics for the space are not achieved, the method further comprises:
performing one of:
   obtaining a suggestion input for adjusting at least one of: the geometry of the space, the one or more materials selected for designing the one or more surfaces or their portions; or
   adjusting the second set of materials, updating the proposal to include the adjusted second set of materials and their corresponding acoustic properties, and receiving a selection of one or more materials from the adjusted second set of materials; and
updating the visio-acoustic XR simulation of the space, based on the obtained suggestion input or the received selection of the one or more materials from the adjusted second set of materials.

In this regard, the term “suggestion input” refers to a user-provided suggestion or modification that is used to address mismatch between current visio-acoustic XR simulation results and the target acoustic metrics of the space, indicated by the test feedback. The suggestion input can guide adjustment in the at least one of: the geometry of the space, the one or more materials selected for designing the one or more surfaces or their portions. The aforementioned adjustments are made by the user. It is to be noted that the adjustment of the geometry of the space may include alterations to the spatial dimensions, surface arrangements and the like geometric attributes that facilitates achievement of the target acoustic metrics. Moreover, the adjustment of the one or more materials chosen for designing the one or more surfaces and their portions, may include replacing the materials, changing their properties, or reassigning them to specific surfaces. Alternatively, the second set of materials is adjusted by the system based on identified deficiencies from the test feedback. The adjusted second set of materials, along with their corresponding acoustic properties is integrated with the proposal provided by the user to update the proposal. This ensures transparency in how the adjustments are reflected in the design of the space. The user interacts with the updated proposal and select the one or more materials from the adjusted second set of materials to design the space that meets the target acoustic metrics. This selection forms the basis for next iteration or finalization of the design of the space. It is to be noted that the obtained suggestion input or the received selection of the one or more materials from the adjusted second set of materials, are incorporated into visio-acoustic XR simulation to update the visio-acoustic XR simulation, ensuring it reflects design changes and provides accurate acoustic predictions. It will be appreciated that continuously updating the visio-acoustic XR simulation ensures the method remains adaptable and capable of producing optimal designs under evolving constraints or suboptimal initial results. A technical effect of the aforementioned feature is to introduces an iterative feedback loop, enabling incremental improvements to achieve optimal acoustic performance of the space in visio-acoustic XR simulation. Additionally, this process minimizes time and resources by identifying and addressing specific shortcomings in the design early in the visio-acoustic XR simulation phase.

Optionally, the computer-implemented method further comprises:
generating a visualization of the soundscape using a visualization module, wherein the visualization of the soundscape depicts at least an interaction of the at least one sound with the one or more surfaces of the space; and
providing the visualization of the soundscape on at least one of: the user device, the XR device.

In this regard, the term “visualization” refers to a visual depiction or a graphical representation of the soundscape within the visio-acoustic XR simulation of the space. It is to be noted that the visualization depicts the propagation of the at least one sound, interactions of the at least one sound with the one or more surfaces (e.g., reflection, absorption, scattering, diffraction, reverberation), spatial characteristics of the soundscape (such as sound intensity, directionality, and distribution), and dynamic acoustic effects like decay over time. Optionally, when the at least one sound comprises a plurality of sounds, the visualization of the soundscape also depicts an interference of the plurality of sounds. It will be appreciated that purpose of the visualization is to provide an intuitive, real-time, or pre-rendered visual interface that helps users understand and analyze the soundscape within the space. The term “visualization module” refers to a software module that is integrated into visio-acoustic XR simulation system to convert the soundscape into visual formats. The visualization module generate 2D or 3D visualizations of the soundscape, depicting acoustic phenomena in a spatially accurate manner. The visualization is delivered to the at least one: the user device, the XR device. This enables immersive visualization in the XR environment, allowing the user to interact with the visio-acoustic XR simulation dynamically for analysis. A technical effect of the visualization is to graphically represent the complex acoustic phenomena of the soundscape and to enhance the user's understanding of the space's acoustic performance. Additionally, by visualizing the soundscape interactions, the user can quickly identify areas for improvement and take corrective actions. Optionally, the system provides a visual representation of the sound propagation and reflection patterns within the virtual space, including wave interactions with surfaces, color-coded material reflections, and animations of acoustic phenomena such as interference and decay.

Optionally, the computer-implemented method further comprises:
obtaining at least one of: space-related metadata, images representing the space;
processing the at least one of: space-related metadata, images representing the space, for extracting geometry information therefrom, wherein the geometry information is used at the step of defining the geometry of the space.

In this regard, the space-related metadata is indicative of: physical characteristics of the space (for example, the spatial dimension, number of surfaces, geometrical details, structural features, patterns and the like), acoustic characteristics of the space (such as the reflection coefficients of the space, the absorption coefficients, diffusion characteristics and the like), environmental context (for example, temperature, humidity, air pressure, acoustic zones and the like), object information (such as details of furniture, position and composition of the object) and the like. Moreover, the images representing the space is obtained from a teleport device. The images may include photographs, LiDAR scans or 3D models of the space. These images facilitate the user to analyse the visio-acoustic XR simulation from a distant place. The space-related metadata, the images representing the space are processed to extract the geometry information of the space. For the images, image recognition or computer vision techniques (e.g., edge detection, depth mapping) are used to infer structural features like the walls, the floors and the ceilings. The processed data provides detailed geometry information, such as surface locations, orientations, and spatial relationships, which are then used to define the geometry of the space in the visio-acoustic XR simulation. A technical effect of the aforementioned feature is that the ability to process both the space-related metadata and the images makes the method adaptable to various input formats, supporting flexible use across different scenarios. Accurate geometry leads to more immersive and visually coherent visio-acoustic XR simulation. Additionally, automated extraction reduces errors and manual intervention, providing the user with faster and more reliable space definitions.

The present disclosure also relates to the system as described above. Various embodiments and variants disclosed above, with respect to the aforementioned method, apply mutatis mutandis to the method.

Notably, the at least one processor controls an overall operation of the system. The at least one processor is communicably coupled to the data repository. Optionally, the at least one processor is implemented as a processor of a user device. Examples of the user device include, but are not limited to, a laptop, a desktop PC, a tablet, a phablet, and a console. Alternatively, optionally, the at least one processor is implemented as a cloud server (namely, a remote server) that provides a cloud computing service.

Optionally, the processor is comprised in one of: the XR device, a computing device associated with the XR device. In some implementations, the processor is integrated with the XR device. Optionally, in such implementations, the processor of the XR device serves as the at least one processor. Alternatively, optionally, in such implementations, the at least one processor is communicably coupled to the processor of the XR device.

In other implementations, the at least one processor is implemented separately from the XR device. In such implementations, the at least one processor is implemented in a distributed manner. Optionally, in this regard, the at least one processor of the acoustic apparatus and the processor of the XR device are communicably coupled. As an example, the at least one processor could be implemented as a processor of the computing device that is communicably coupled to the XR device. The computing device could, for example, be a laptop, a desktop, a tablet, a phablet, a personal digital assistant, a workstation, a console, or similar. As another example, the at least one processor could be implemented as at least one server that is communicably coupled to the XR device. The at least one server may, for example, be implemented as a cloud server.

It will be appreciated that the at least a first database comprising acoustic properties of a plurality of materials is stored in the data repository that is communicably coupled to the at least one processor. Optionally, the second database is also stored at the data repository. Examples of the data repository include, but are not limited to, a memory of the at least one processor, a memory of the computing device, a removable memory, and a cloud-based database.

Optionally, the user device is one of: an XR device, a computing device. In this regard, the computing device could, for example, be a smart phone, a laptop, a desktop, a tablet, a phablet, a personal digital assistant, a workstation, a console, or similar. The user may directly provide inputs at the XR device or may provide inputs at the XR device via accessories associated with the XR device. The accessories may include UI controllers, keyboards, mouse, pucks, and the like. It is to be noted that the computing device may or may not be associated with the XR device. For example, the computing device may be an XR console associated with the XR device. The association is that the XR console may render XR image frames that are to be displayed at the XR device. In another example, the computing device may be a personal smartphone or tablet of the user of the XR device. This computing device may not necessarily be responsible for rendering XR image frames. A technical effect of the aforementioned feature is to ensure compatibility across different work environments, from XR-powered simulations to desktop-based architectural planning.

### DETAILED DESCRIPTION OF THE DRAWINGS

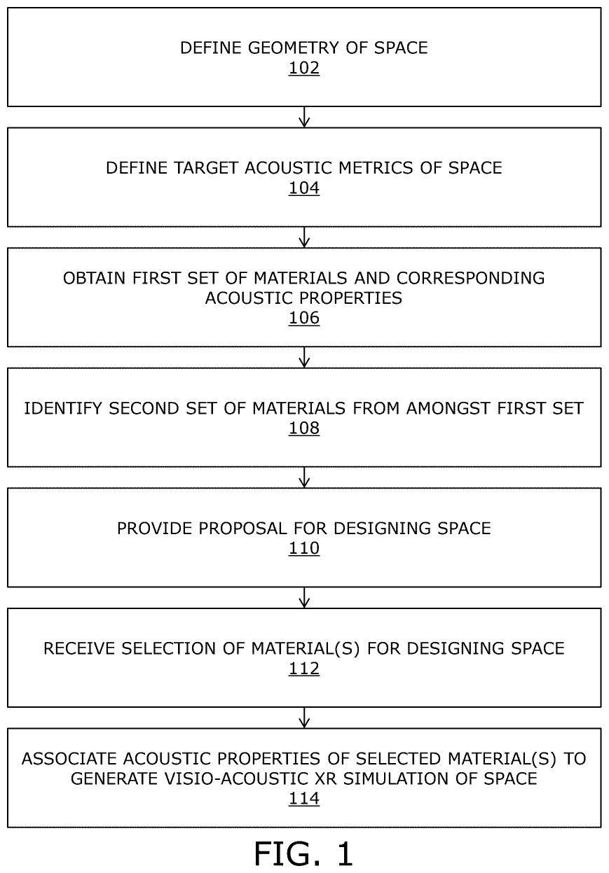

Referring to FIG. 1, illustrated are steps of a method for interactively generating a visio-acoustic extended-reality (XR) simulation of a space, in accordance with an embodiment of the present disclosure. At step 102, a geometry of the space is defined. At step 104, target acoustic metrics for the space is defined. At step 106, a first set of materials and their corresponding acoustic properties is obtained, from a first database. At step 108, a second set of materials is identified from amongst the first set of materials, by analysing a correspondence between the target acoustic metrics and the acoustic properties of the materials of the first set, and the geometry of the space. At step 110, at a user device, a proposal for designing one or more surfaces of the space is provided, the proposal includes the second set of materials and their corresponding acoustic properties. At step 112, from the user device, a selection of one or more materials is received from the second set for designing the one or more surfaces or their portions. At step 114, corresponding acoustic properties of the one or more materials are associated to the one or more surfaces or their portions, for generating the visio-acoustic XR simulation of the space.

The aforementioned steps are only illustrative and other alternatives can also be provided where one or more steps are added, one or more steps are removed, or one or more steps are provided in a different sequence without departing from the scope of the claims herein.

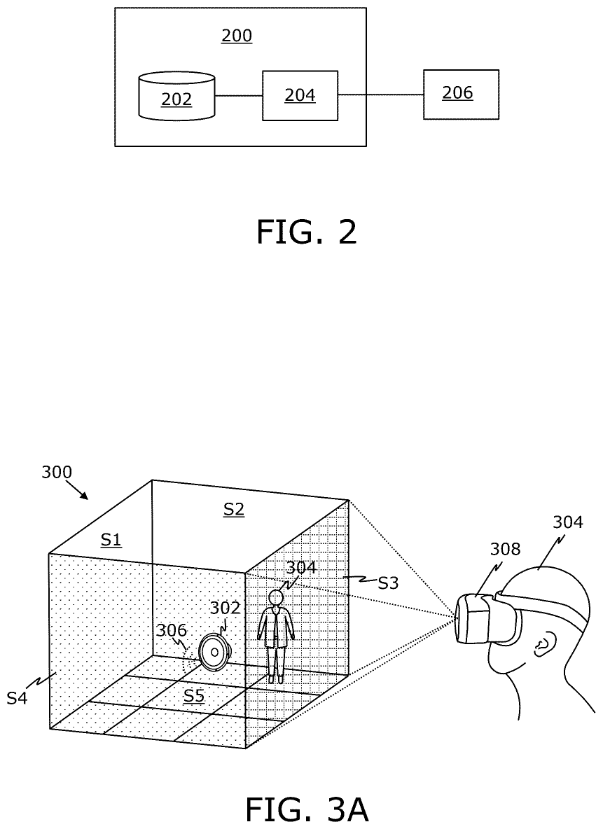

Referring to FIG. 2, illustrated is a block diagram of a system 200 for interactively generating a visio-acoustic extended-reality (XR) simulation of a space, in accordance with an embodiment of the present disclosure. The system 200 comprises a data repository 202 and a processor 204 communicably coupled to the data repository 202. The processor 204 is communicably coupled to a user device 206. The processor 204 is configured to perform various operations, as described earlier with respect to the aforementioned second aspect.

It may be understood by a person skilled in the art that FIG. 1 includes a system 200 for interactively generating a visio-acoustic extended-reality (XR) simulation of a space, for sake of clarity, which should not unduly limit the scope of the claims herein. It is to be understood that the specific implementation of the system 200 is provided as an example and is not to be construed as limiting it to specific numbers or specific types of data repository 202 and processor 204. The person skilled in the art will recognize many variations, alternatives, and modifications of embodiments of the present disclosure.

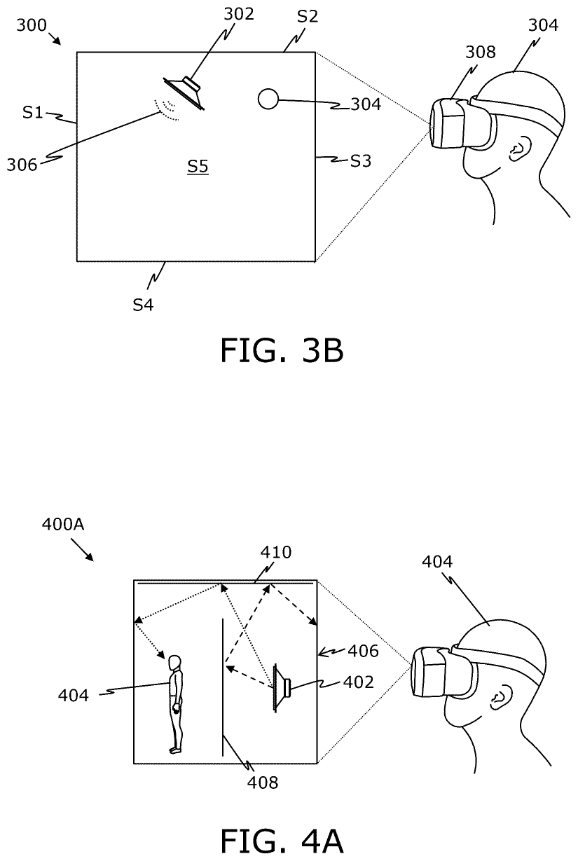

Referring to FIGS. 3A and 3B, FIG. 3A is a schematic illustration of a three-dimensional (3D) virtual space 300 for which a visio-acoustic extended-reality (XR) simulation is generated, while FIG. 3B is a schematic illustration of a top view of the 3D virtual space 300 of FIG. 3A, in accordance with an embodiment of the present disclosure. With reference to FIG. 3A, the space 300 represents a living room comprising one or more surfaces (S1, S2, S3, S4, S5) (ceiling is not shown for the sake of clarity). For example, the surfaces S1, S2, S3, and S4 are four walls of the space 300, while the surface S5 is a floor of the space 300. For sake of clarity, the surfaces S3 and S4 are represented by a square hatching pattern and a dotted hatching pattern, respectively. Optionally, the space 300 comprises at least one virtual sound source (depicted as a virtual sound source (namely, a loudspeaker 302) in the visio-acoustic XR simulation. Optionally, the 3D space 300 comprises at least one sound receiver depicted as a sound receiver 304) and at least one sound (depicted as a sound 306) emitted by the at least one virtual sound source 302. For example, the sound receiver 304 is a user who is wearing a HMD device 308 and an audio device, using the HMD device to perform the XR simulation of and an audio device to hear the sound 306 generated in a virtual space 300. The sound receiver 304 uses the HMD device 308 to see the visuals of the virtual space 300 and the objects presents in the virtual space 300. The sound receiver 304 uses the audio device to hear the sound 306 generated by the at least one sound source 302 to analyse the visio-acoustic XR simulation within the.

With reference to FIG. 3B, the space 300 represents the top view of the 3D virtual space (for the sake of clarity). Herein, the sound 306 is emanating from the virtual sound source 302 (namely, the loudspeaker acting as the sound source).

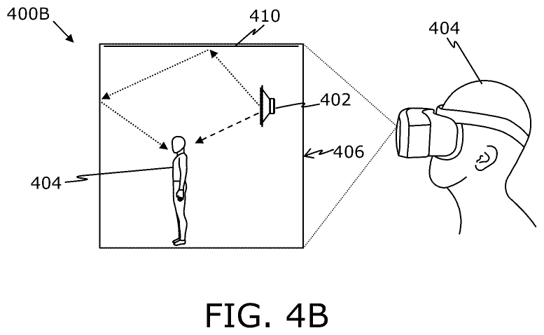

Referring to FIGS. 4A and 4B, illustrated are simplified illustrations of a side view of exemplary soundscapes 400A and 400B of a space, respectively, in accordance with different embodiments of the present disclosure. The virtual space 406 comprises at least one virtual sound source 402 and at least one sound receiver 404 (namely, the user wearing the HMD device). The soundscapes 400A and 400B comprise an auditory response received at the at least one sound receiver 404, corresponding to the simulated emission of at least one sound produced by the virtual sound source 402. For example, the at least one sound comprises a first sound (whose path is depicted via dashed arrows) and a second sound (whose path depicted via dotted arrows). Optionally, the soundscapes 400A and 400B comprises an impulse response indicative of how sound is expected to propagate in the space 406, based on the geometry of the space 406 and the acoustic properties of the one or more materials. With reference to FIG. 4A, the space 406 comprises a reflective and sound insulating partition wall 408. The first sound struck the wall 408 and reflected towards an absorptive ceiling 410. The first sound then reflected from the absorptive ceiling 410 of the space 406 and reached a virtual wall of the virtual space 406. The second sound struck the absorptive ceiling 410 of the space 406 and got reflected towards a wall of the space 406. Thereafter, the second sound struck the wall of the space 406 and got reflected before reaching the at least one sound receiver 404 (just to highlight a simplified version of sounding movement in the space 406). The soundscape 400A does not have any direct sound and shows only reflections of sound (early reflections, late reflections, reverberation) through the absorptive ceiling 410 and the reflected and sound insulating partition wall 408 of the space 406.

With reference to FIG. 4B, the space 406 is without a reflective and sound insulating partition wall. The soundscape 400B shows the first sound (whose path depicted via dashed arrows) (optionally, known as direct sound) is emitted from the at least one virtual sound source 402 is received by the at least one sound receiver 404 directly without any reflections due to absence of the insulating wall. The second sound (whose path is depicted via dotted arrows) struck the absorptive ceiling 410 of the space 406 and got reflected towards a wall of the space 406. Thereafter, the second sound struck the wall of the space 406 and got reflected before reaching the at least one sound receiver 404.

Modifications to embodiments of the present disclosure described in the foregoing are possible without departing from the scope of the present disclosure as defined by the accompanying claims. Expressions such as “including”, “comprising”, “incorporating”, “have”, “is” used to describe and claim the present disclosure are intended to be construed in a non-exclusive manner, namely allowing for items, components or elements not explicitly described also to be present. Reference to the singular is also to be construed to relate to the plural.

1. A computer-implemented method for interactively generating a visio-acoustic extended-reality (XR) simulation of a space, the method comprising:
defining a geometry of the space;
defining target acoustic metrics for the space;
obtaining a first set of materials and their corresponding acoustic properties, from a first database;
identifying a second set of materials from amongst the first set of materials, by analysing a correspondence between the target acoustic metrics and the acoustic properties of the materials of the first set, and the geometry of the space;
providing, at a user device, a proposal for designing one or more surfaces (S1, S2, S3, S4, S5) of the space, the proposal including the second set of materials and their corresponding acoustic properties;
receiving, from the user device, a selection of one or more materials from the second set for designing the one or more surfaces or their portions; and
associating corresponding acoustic properties of the one or more materials to the one or more surfaces or their portions, for generating the visio-acoustic XR simulation of the space.

2. The computer-implemented method of claim 1, wherein the geometry of the space comprises at least one of: spatial dimensions, a number of surfaces, physical surface design information, pre-defined surface material information, object information, environmental context, acoustic zones, of the space.

3. The computer-implemented method of claim 1, wherein the target acoustic metrics comprise at least one of: Speech Transmission Index (STI), noise level, reverberation time (RT60), audio level, clarity and intelligibility parameters, spatialization parameters, auditor envelope.

4. The computer-implemented method of claim 1, wherein the step of identifying the second set of materials from amongst the first set of materials is performed by employing at least one of: a logical operation, a simulation, an artificial intelligence algorithm.

5. The computer-implemented method of claim 1, further comprising:
providing the visio-acoustic XR simulation of the space, at an XR device;
receiving a test input indicative of:
a location and audio properties of at least one virtual sound source in the visio-acoustic XR simulation of the space, and
a location of at least one sound receiver in the visio-acoustic XR simulation of the space;
simulating emission of at least one sound by the at least one virtual sound source; and
generating a soundscape comprising an auditory response received at the at least one sound receiver, corresponding to the simulated emission of the at least one sound.

6. The computer-implemented method of claim 5, wherein the step of generating the soundscape comprises:
generating an impulse response indicative of how sound is expected to propagate in the space, based on the geometry of the space and the acoustic properties of the one or more materials; and
convolving the generated impulse response with the at least one sound, for generating the auditory response.

7. The computer-implemented method of claim 6, wherein the impulse response is generated using at least one of: a numerical simulation processing, a geometrical acoustic processing.

8. The computer-implemented method of claim 5, further comprising:
providing the soundscape in the visio-acoustic XR simulation of the space;
receiving test feedback indicative of whether the target acoustic metrics for the space are achieved, based on the provided soundscape; and
maintaining the visio-acoustic XR simulation of the space, based on the test feedback.

9. The computer-implemented method of claim 8, wherein when the test feedback indicates that the target acoustic metrics for the space are achieved, the method further comprises storing the visio-acoustic XR simulation of the space, in a second database, wherein the stored visio-acoustic XR simulation of the space is accessible for generating future visio-acoustic XR simulations of other spaces.

10. The computer-implemented method of claim 8, wherein when the test feedback indicates that the target acoustic metrics for the space are not achieved, the method further comprises:
performing one of:
obtaining a suggestion input for adjusting at least one of: the geometry of the space, the one or more materials selected for designing the one or more surfaces (S1, S2, S3, S4, S5) or their portions; or
adjusting the second set of materials, updating the proposal to include the adjusted second set of materials and their corresponding acoustic properties, and receiving a selection of one or more materials from the adjusted second set of materials; and
updating the visio-acoustic XR simulation of the space, based on the obtained suggestion input or the received selection of the one or more materials from the adjusted second set of materials.

11. The computer-implemented method of claim 5, further comprising:
generating a visualization of the soundscape using a visualization module, wherein the visualization of the soundscape depicts at least an interaction of the at least one sound (306) with the one or more surfaces of the space (S1, S2, S3, S4, S5); and
providing the visualization of the soundscape on at least one of: the user device, the XR device.

12. The computer-implemented method of claim 1, further comprising:
obtaining at least one of: space-related metadata, images representing the space;
processing the at least one of: space-related metadata, images representing the space, for extracting geometry information therefrom, wherein the geometry information is used at the step of defining the geometry of the space.

13. A system for interactively generating a visio-acoustic extended-reality (XR) simulation of a space, the system comprising:
a data repository having stored thereat at least a first database comprising acoustic properties of a plurality of materials; and
a processor communicably coupled to the data repository, wherein the processor is configured to:
define a geometry of the space;
define target acoustic metrics for the space;
obtain a first set of materials and their corresponding acoustic properties, from the first database;
identify a second set of materials from amongst the first set of materials, by analysing a correspondence between the target acoustic metrics and the acoustic properties of the materials of the first set, and the geometry of the space;
provide, at a user device, a proposal for designing one or more surfaces of the space, the proposal including the second set of materials and their corresponding acoustic properties;
receive, from the user device, a selection of one or more materials from the second set; and
associate corresponding acoustic properties of the one or more materials to the one or more surfaces or their portions, to generate the visio-acoustic XR simulation of the space.

14. The system of claim 13, wherein the user device is one of: an XR device, a computing device.

15. The system of claim 13, wherein the processor is comprised in one of: the XR device, a computing device associated with the XR device.
